(19) United States
(12) Patent Application Publication
(10) Pub. No.: US 2006/0082355 A1
(43) Pub. Date: Apr. 20, 2006

(54) Test pulses for enabling revenue testable panel meters

(75) Inventor: Erran Kagan, Great Neck, NY (US)

Correspondence Address: DILWORTH & BARRESE, LLP, 333 EARLE OVINGTON BLVD., UNIONDALE, NY, 11553, US

(73) Assignee: ELECTRO INDUSTRIES/GAUGETECH, WESTBURY, NY (US)

(21) Appl. No.: 10/969,713

(22) Filed: Oct. 20, 2004

(51) Int. Cl. G01R 35/04

(52) U.S. Cl. 324/74

(57) ABSTRACT

A panel meter including an energy test pulse device that enables the panel meter to be used for revenue applications and eliminates the need for two separate meters, one for panel indication, and the other for energy and revenue applications.

### BACKGROUND OF THE INVENTION

1. Field of the Invention

The present invention relates generally to electrical panel meters, and more specifically to a system and method for utilizing test pulses in the electrical panel meters to enable their use for revenue metering.

2. Discussion of the Related Prior Art

Electric utility companies use revenue meters to track electric usage by customers. These meters track the amount of power consumed at a particular location. These locations range from commercial businesses, to residential homes. The electric utility companies use the revenue meter to charge its customers for their power consumption, i.e., revenue metering. Typically, the revenue meter connects between utility power lines supplying electricity and a usage point, namely a residence or commercial place of business.

Traditionally, panel mounted or panel meters were utilized only for a visual indication of instantaneous readings on an electrical switchboard panel. In the past, these panel meters were exclusively analog, and were utilized for measuring the amount of voltage, current, wattage etc., supplied to consumers through the utility lines. As metering technology progressed, the panel meters became multifunction, and have the ability to measure energy as well as instantaneous measurements.

However, even though the panel meters had the ability to measure energy, the panel meters did not have the ability to be tested and verified for accuracy using traditional Utility testing methods. Therefore, they would not have the capability to be used for revenue billing measurements.

Traditionally, revenue meters used mechanical or analog means to track the amount of consumed power. The inductive spinning disk power meter is still commonly used. The spinning disk drives mechanical counters that track the power consumption information. Newer to the market are electronic power meters, which have replaced the older mechanical meters. Electronic revenue meters utilize digital sampling of the voltage and current waveforms to generate power consumption information. In addition to monitoring power consumption, electronic revenue meters can also monitor and calculate power quality, e.g., voltage, current, real power, reactive power, apparent power, etc. These power quality measurements and calculations are displayed on an output display device on the meter.

The traditional method for testing the revenue meters is to take an infrared pulse supplied by the analog meter, which pulses proportionally to the energy accumulated. The standard revolution value is 1.8 watt-hours per pulse, but this value is generally adjustable. The pulses are then counted and compared to pulses generated by a standard energy reference. If the accuracy of the taken infrared pulses is within the percentage required by the industry standards, then the power meter would be determined to be in good standing and put into service. Otherwise, the meter would be re-calibrated and tested again or not used.

Therefore, since the veracity of the panel measuring device could not be determined in the field through the use of traditional methods and equipment, as described above, these meters would not be used for the billing purpose as the supplied data can potentially be erroneous.

### SUMMARY OF THE INVENTION

Therefore, the present invention has been designed to substantially solve at least the above problems and/or disadvantages and to provide at least the advantages below.

Accordingly, an object of the present invention is to provide an electrical metering device capable of performing multiple metering functions including an energy test devices for testing a veracity of an energy measurement of the electrical panel metering device.

According to another object of the present invention, a method for testing a veracity of an energy measurement of an electrical panel metering device is provided. The method includes the step of proving an energy test pulse to verify the energy measurement of the electrical panel metering device.

### BRIEF DESCRIPTION OF THE DRAWINGS

The above and other objects, features, and advantages of the present invention will become more apparent from the following detailed description when taken in conjunction with the following drawings in which:

FIG. 1 illustrates a block diagram of a panel meter including an energy test pulse according to a preferred embodiment of the present invention.

### DETAILED DESCRIPTION OF THE PREFERRED EMBODIMENTS

The present invention provides a method for assuring accuracy in verifying a panel meter, thereby enabling such panel meters to be used as power meters for the purpose of revenue metering. Verification of accuracy determines if the electronic panel meter is calibrated to within the standard traditionally used in the Utility industry for verifying veracity of electronic panel meters to enable such meter to be used as utility revenue meters.

More specifically, panel meters according to the present invention are designed to provide Real Time indication, not merely energy usage indication. The panel operators are looking for the load on a bank or the voltage. The present invention performs this function, but also provides revenue certifiable energy data that can be brought back to the central monitoring system. Conventionally, this was a function that was relegated to “higher end” revenue metering.

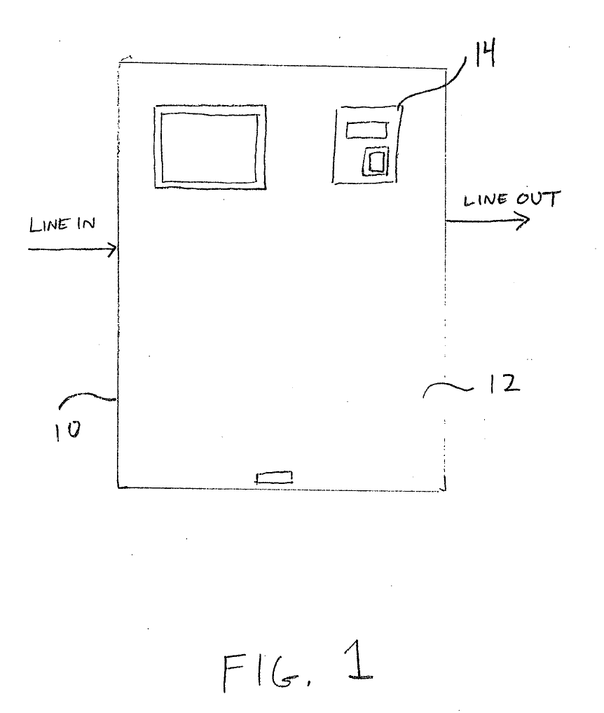

The present invention provides an electronic panel meter that includes an energy test pulse. FIG. 1 illustrates an electronic panel meter 10 having a front face panel 12. An energy test pulse device 14, which generates an infrared test pulse, is applied to the front face 12 of the panel meter 10. In the preferred embodiment of the present invention, the test pulse device 14 is added to the front face 12 of the electronic panel meter 10, which automatically pulses in proportion to the energy used. Sending infrared pulses in accordance with the amount of energy used is known to those skilled in the art.

That is, there are many test pulse devices. They are generally referred to in the industry as “energy test standards”. They generate pulses proportional to accumulated energy. These are used for testing accumulated energy. There are also devices that can measure the voltage, current and phase angle magnitude for accuracy of real-time readings. Basically, they are highly accurate multi-meters.

By providing an ability to determine the calibration veracity for accumulated energy of an electrical panel meter using standard field accepted testing methods designed for a different class of product, the present invention enables a panel meter, an significant lower cost and smaller device, to be used for revenue applications and eliminates the need for two separate meters, one for panel indication, and the other for energy and revenue applications.

While the present invention has been shown and described with reference to a certain preferred embodiment thereof, it will be understood by those skilled in the art that various changes in form and details, may be made therein without departing from the spirit and scope of the present invention.

What is claimed is:

1. An electrical metering device capable of performing multiple metering functions comprising an energy test devices for testing a veracity of an energy measurement of the electrical panel metering device.

2. The device of claim 1, wherein the energy test device is an infrared pulse.

3. The device of claim 1, wherein the multiple metering functions include a Real Time indication function.

4. A method for testing a veracity of an energy measurement of an electrical panel metering device comprising the step of proving an energy test pulse to verify the energy measurement of the electrical panel metering device.

5. The method of claim 4, wherein the energy test pulse is an infrared pulse.
